(19) United States
(12) Patent Application Publication
(10) Pub. No.: US 2005/0225207 A1
(43) Pub. Date: Oct. 13, 2005

(54) Belt piezoelectric generator

(76) Inventor: Michio Tsujiura, Shizuoka (JP)

Correspondence Address: ANDERSON, KILL & OLICK, P.C., 1251 AVENUE OF THE AMERICAS, NEW YORK,, NY, 10020-1182, US

(21) Appl. No.: 10/817,237

(22) Filed: Apr. 2, 2004

(51) Int. Cl. H01L 41/08

(52) U.S. Cl. 310/328

(57) ABSTRACT

In accordance with the present invention stable and continuous alternate current may be collected by mechanically moving a multi-electrode piezoelectric endless ceramic belt between two rows of rollers so that the belt forms a wavy shape. A piezoelectric power generator is formed from a piezoelectric ceramic belt arranged to form an endless loop comprising an upper and lower side containing multiple electrodes on each side thereof in an arrangement forming multiple pairs of electrodes with the electrodes being polarized upon the application of high voltage and further comprising two rows of rollers adapted to be driven by a conventional drive source alternately arranged for driving the belt in a continuous wavy motion and having current collecting means for continuously generating electric power from the moving piezoelectric ceramic belt.

### TECHNICAL FIELD

The present invention is directed to a piezoelectric power generator and to a method of forming a piezoelectric ceramic belt for power generation. There is no known piezoelectric power generator capable of generating electricity at output levels suitable for commercial application. Moreover, there is no known piezoelectric power generator which will generate electric energy by continuously moving a piezoelectric ceramic belt.

### BACKGROUND

To date piezoelectric ceramics are known to generate very small amounts of electrical energy. For this reason piezoelectric ceramic elements have not been considered in the manufacture of a useful power generator where large amounts of energy represent a technical limitation.

The present invention provides a simplified structure for generating high levels of electrical energy from a piezoelectric ceramic belt arranged to form an endless loop which is moved continuously to provide high efficiency power generation.

### SUMMARY OF THE INVENTION

The present invention is a piezoelectric power generator comprising a piezoelectric ceramic belt arranged to form an endless loop with the belt having an upper and lower side containing multiple electrodes on each side thereof in an arrangement forming multiple pairs of electrodes with the electrodes being polarized upon the application of high voltage and with said generator further comprising two rows of rollers adapted to be driven by a conventional drive source with the rollers alternately arranged for driving the belt to cause continuous wavy motion and having current collecting means for continuously generating electric power from the moving piezoelectric ceramic belt.

The present invention also covers a method of forming a piezoelectric ceramic belt for generating electrical power made by the steps of: depositing a multiple even number of electrodes on a first surface of an endless belt; placing a first and second electrical pickup line on opposite sides of the first surface; depositing a multiple even number of electrodes of the same size and shape as electrodes on a second surface of the endless belt opposite the first surface; placing a first and second electrical pickup line on opposite sides of the second surface; applying a high voltage to all electrode paired segments to polarize them such that only electrode paired segments are given piezoelectric ceramic properties; forming a connecting line between alternate odd numbered of the electrodes and connecting the connecting line to the first electrical pickup line; forming a connecting line between alternate even numbered of the electrodes and connecting the connecting line to the second electrical pickup line; forming a connecting line between alternate odd numbered of the electrodes and connecting the connecting line to the first electrical pickup line; forming a connecting line between alternate even numbered of the electrodes and connecting the connecting line to the second electrical pick up line; whereby an electrical circuit is formed connecting the electrodes and to all of the respective pick up lines via connecting lines.

### BRIEF DESCRIPTION OF THE DRAWINGS

FIGS. 1(A-C) are partial perspective views of an endless multi-electrode piezoelectric ceramic belt arranged in accordance with the present invention to form a piezoelectric power generator;

FIGS. 2A and 2B are cross sectional views of the piezoelectric ceramic belt of FIG. 1;

FIG. 3 is a partial perspective view of an arrangement of driving rollers for continuously driving the piezoelectric ceramic belt of FIG. 1 to form a piezoelectric power generator in accordance with the present invention.

FIG. 4 is a partial view (cross section) of the present invention.

FIG. 5 is also a partial view (cross section) of the present invention.

### DETAILED DESCRIPTION OF THE INVENTION

Embodiments of the present invention are described below with reference to all of the drawings.

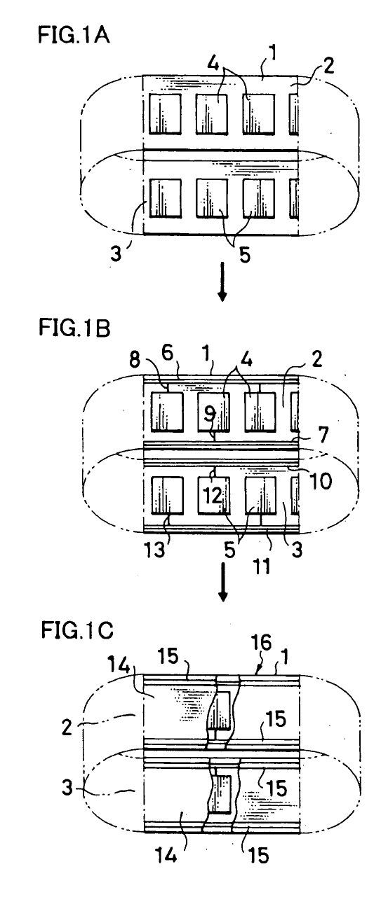

The partial perspective views in FIG. 1 (A-C) illustrate an endless multi-electrode piezoelectric ceramic belt 1 arranged in an endless loop of circular or elliptical geometry. The endless piezoelectric ceramic belt 1 has an upper or outer circumference 2 and a lower or inner circumference 3 with the outer circumference 2 and inner circumference 3 each having multiple electrodes 4 and 5 formed thereon respectively preferably by screen printing or using another conventional deposition process. The screen printing operation can be performed with a conductive silver alloy paste There should be an even number of electrodes on each surface with the corresponding electrodes on each side arranged to form electrode pairs, i.e., the electrodes are of the same size and shape and are in corresponding alignment relative to one another on each surface. The electrodes are also preferably uniformly centered along the belt 1 to provide space on either side thereof for placement of an independent electrical pickup line at a given location along the surface of each outer and inner circumference with the pick up line preferably located at either the front or back end of the belt 1 relative to the central position of the electrodes. The electrical pickup line should be preferably formed by a printing or deposition process similar to that used in forming the electrodes and preferably along the same points on the inner circumference 3 as on the outer circumference 2. After the electrodes and the electrical pick up lines are formed a high voltage is applied to all of the electrode pairs to polarize each segmented pair so as to cause piezoelectric ceramic properties.

A first electrical pick up line 6 should be formed at or adjacent a first edge of the outer circumference 2 of belt 1, and a second electrical pickup line 7 should be formed at a second edge of the outer circumference 2 of belt 1 opposite the first edge, utilizing e.g., a conductive ink such as a silver paste. A connecting line 8 is formed on the outer circumference 2 to connect every other electrode 4, designated the odd numbered of the electrodes 4, to the first electrical pickup line 6. Another connecting line 9 should be formed on the outer circumference 2 also utilizing a conductive ink such as a silver paste to connect every other electrode 4 designated the even numbered electrodes 4 to the second electrical pickup line 7, thereby forming a common electrical circuit for connecting the electrodes 4 to the pick up lines 6 and 7 via connecting lines 8 and 9 respectively. It should be understood that the total number of electrodes 4 is an even number.

Similarly, first and second electrical pick up lines 10 and 11 are screen printed or deposited along opposite edges on the inner circumference 3 of belt 1 utilizing a good conductive ink such as a silver paste; and a connecting line 12 to connect every other electrode 5, designated the odd numbered of the electrodes 5, to the first electrical pickup line 10 and further screen printing a connecting line 13 to connect every other electrode 5 designated the even numbered of the electrodes 5, to the second electrical pickup line 11, thereby providing an electrical circuit for connecting the electrodes 5 to the pick up lines 10 and 11 via connecting lines 12 and 13 respectively. Again, the total number of electrodes 5 is an even number.

The process of forming an endless piezoelectric ceramic belt 1 further includes the steps of coating the surface of the outer circumference 2 and the inner circumference 3 with an insulating thin film 14 for surface protection; and coating the first electrical pickup line 6 and second electrical pickup line 7 on the outer surface 2 and the first electrical pickup line 10 and the second electrical pickup line 11 on the inner surface 3, with a conductive film 15 utilizing a metallic foil or a conductive thin film plastic, thereby forming, after the electrodes are polarized by application of high voltage, a multi-electrode piezoelectric ceramic belt 16.

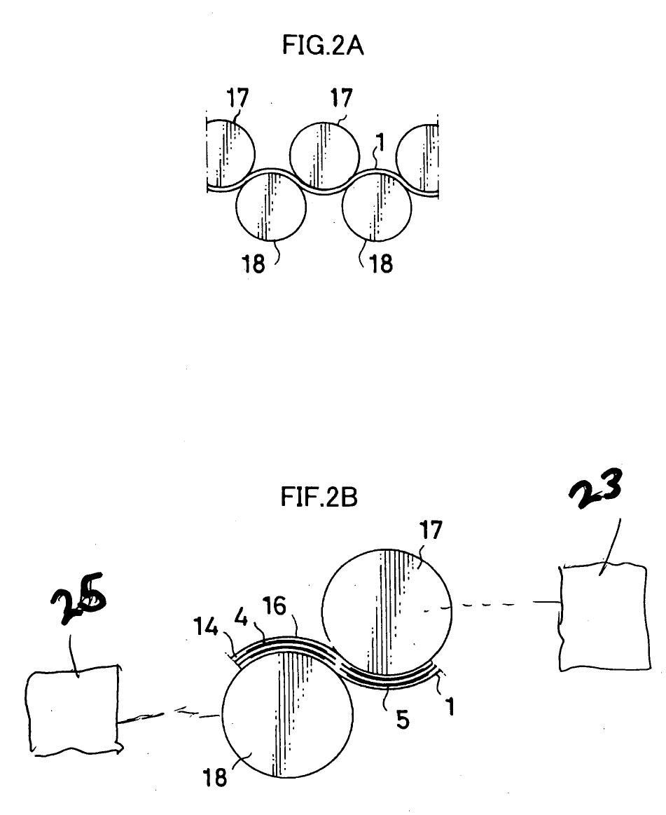

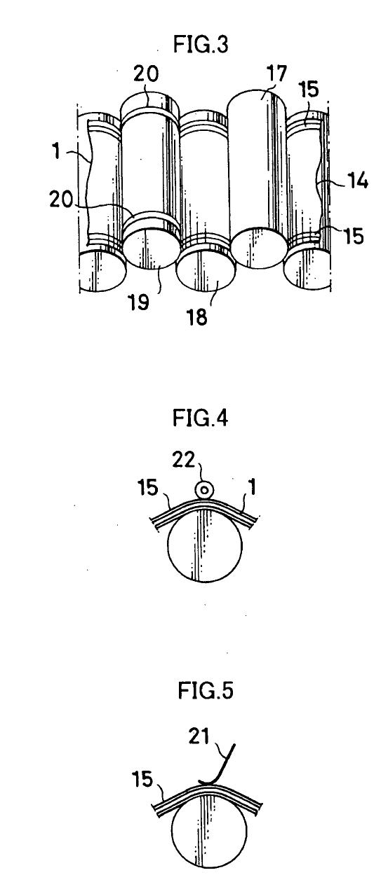

FIGS. 2 (A) (B) are cross sectional views of the basic configuration of the present invention. FIG. 3 is a simplified perspective view of the basic configuration of the present invention in which a circular multi-electrode piezoelectric ceramic belt 16 (hereinafter referred to as “ceramic belt 16”) is interposed between two displaced rows of rollers 17 and rollers 18 with the ceramic belt 16 spaced between the outer circumference of the pressing rollers 17 (hereinafter referred to as the “outer rollers 17”) and the inner circumference of the pressing rollers 18 (hereinafter referred to as the “inner rollers 18”).The rows of rollers 17 and rollers 18; are alternately spaced to cause the ceramic belt 16 to assume a wavy shape in the form of a sinusoid or continuous S-shape. The outer rollers 17 and inner rollers 18 are made of insulating material and are driven by any conventional drive means 23 and 25 representing for example power drive rollers which are either motorized or driven by a drive mechanism employing gears, a timing belt or a V-belt, etc.

All outer rollers 17 and all of the inner rollers 18 are driven to rotate in a direction opposite to each other so that the multi-electrode piezoelectric ceramic belt 16, sandwiched between the outer and inner rollers, will move in a defined unidirectional path.

Electrical pickup rollers 19 having an electrical pickup (collection) rings 20 are provided for as is shown in FIG. 3 so that the electrical pickup ring 20 makes contact with the conductive film 15 in the ceramic belt 16 . Electrical pickup rollers 19 having the same shape as other rollers are provided on the outer circumference where other rollers are present; the outer circumference of the electrical pick-up ring 20 is level with the outer circumference of electrical pickup roller 19 without interruption.

The outer circumferences of the outer rollers 17 and the inner rollers 18 contact the ceramic belt 16. The outer circumference of the electrical collection roller 19, excluding the electrical collection ring 20, is made of an insulating material.

The current collection rings 20 of the electrical collector roller 19 are connected by means of rotary conductors, such as e.g., ring 24 as shown in FIG. 4, to an external electrical circuit (not shown) for collecting and transmitting electricity. The current collector rings 20 make contact via conventional rotary conductors or the like to transmit electricity generated in the piezoelectric ceramic belt to an external transmission circuit (not shown) for further transmission of the electrical energy to a power station or directly for use.

The present invention configured as described above provides the following advantageous effects.

The piezoelectric ceramic portion, which is sandwiched between the polarized electrodes 4 and 5 generates the electrical energy continuously as a result of continuous pinching of the electrode pairs derived from torque applied by the rollers 18 against the ceramic belt. . The resulting electric energy is collected via connecting lines 8 and 9 by electrical pickup line 6 at the first end and electrical pickup line 7 at the second end on the outer circumference 2, and also by electrical pickup line 10 at the first end and electrical pickup line 11 at the second end on the inner circumference 3.

By pinching the ceramic belt 16 between two rows of rollers consisting of outer rollers 17 and inner rollers 18 arranged so that the belt 16 forms a serpentine shape with the outer rollers 17 and the inner rollers 18 alternating the wave shape of the piezoelectric ceramic portion constructed with electrodes 4 and 5 is convex at a point contacting the inner rollers 18 and concave at a point contacting the outer rollers 17. The convex to concave wave shape is cyclical and corresponds to the outer circumference of the rollers.

In this configuration, multi-electrode piezoelectric ceramic belt 16 is protected by thin film coating 14 and conductive film 15. Therefore, it is most unlikely that the rotary motion of rollers damages ceramic belt 16.

When all of the outer rollers 17 including electrical pickup rollers 19 and the inner rollers 18 are rotated at the same speed, the ceramic belt 16 begins its wavy motion together with the piezoelectric ceramic portion sandwiched between the electrodes 4 and 5 on the belt 16 moving unidirectionally in a stable manner.

By designating the concave segment of the electric energy cycle of the piezoelectric ceramic portion sandwiched between electrodes 4 and 5 as the positive current cycle]and by designating the convex segment of the electric energy as the negative current cycle the resulting electric energy has AC current characteristics.

This AC electric energy is picked up by: the first electrical pickup line 6 and the second electrical pickup line 7 via connecting lines 8 and 9 on outer circumference 2; and by the first electrical pickup line 10 and the second electrical pickup line 11 via connecting lines 12 and 13 on outer circumference 3. The AC current is retrieved by external means through the conductive film 15 via the electrical pickup ring 20 on the electrical pickup roller 19.

Since all of the electrodes are forced to repeat the same wavy motion, and generate the same amount of electric energy, the energy extracted will be the sum of the electric energy generated by all electrode segments.

Thus, by continuously moving the endless ceramic belt 16 between the outer rollers 17 and the inner rollers 18, AC current can be continuously taken out as long as desired.

An electrical pickup shoe 21 (FIG. 5) or an electrical pickup ring 22 (FIG. 4) may be used in place of or in conjunction with the electrical pickup rollers 19 to pickup electric energy generated from the endless ceramic belt 16.

1. A piezoelectric ceramic belt (1) for generating electrical power made by the steps of:
depositing a multiple even number of electrodes (4) on a first surface of an endless belt composed of piezoelectric ceramic material;
placing a first (6) and second (7) electrical pickup line on opposite sides of the first surface,
depositing a multiple even number of electrodes 5 of the same size and shape as electrodes 4 on a second surface of the endless belt opposite the first surface;
placing a first (10) and second (11) electrical pickup line on opposite sides of the second surface,
applying a high voltage to all electrode paired segments to polarize them such that only electrode paired segments are given piezoelectric ceramic properties;
forming a connecting line (8) between alternate odd numbered of the electrodes (4) and connecting the connecting line (8) to the first electrical pickup line (6),
forming a connecting line (9) between alternate even numbered of the electrodes 4 and connecting the connecting line (9) to the second electrical pickup line (7),
forming a connecting line (12) between alternate odd numbered of the electrodes (5) and connecting the connecting line (12) to the first electrical pickup line (10)
forming a connecting line (11) between alternate even numbered of the electrodes 5 and connecting the connecting line (11) to the second electrical pick up line (13)
whereby an electrical circuit is formed connecting the electrodes 4 and 5 to the respective pick up lines 6,7 and 10,11 respectively via connecting lines 8,9 and 12, 13 respectively.

2. A piezoelectric ceramic belt (16) as defined in claim 1 further comprising: coating an insulating film on the first surface defining the outer circumference thereof of the belt and on the second surface defining the inner circumference of the multi-electrode piezoelectric ceramic belt and coating a conductive film (15) on each of the electric pickup lines.

3. A belt type piezoelectric power generator for a piezoelectric ceramic belt (16) arranged to form an endless loop with the belt having an upper and lower side containing multiple electrodes on each side thereof in an arrangement forming multiple pairs of electrodes with the electrodes being polarized upon the application of high voltage and with said generator further comprising two rows of rollers adapted to be driven by a conventional drive source with the rollers alternately arranged for driving the belt continuously to cause continuous wavy motion and having current collecting means for continuously generating electric power from the moving piezoelectric ceramic belt with the multi-electrode piezoelectric ceramic belt (16) located between outer rollers (17) and inner rollers (18) which pinch the ceramic belt as it is moved.

4. The belt type power generator of claim 3 wherein electric energy generated by multi-electrode piezoelectric ceramic belt (16) is captured by providing an electrical pickup shoe (21) or electrical pickup ring (22) at a point touching only conductive film 15, which is linearly provided on the outer end of said inner and said outer circumferences.
